(19) United States
(12) Patent Application Publication
(10) Pub. No.: US 2017/0250333 A1
(43) Pub. Date: Aug. 31, 2017

(54) Substrate for Optical Device

(71) Applicant: Point Engineering Co., Ltd., Asan-si (KR)

(72) Inventors: Young Woon Jeon, Ansan-si (KR); Tae Hwan Song, Cheonan-si (KR)

(21) Appl. No.: 15/593,726

(22) Filed: May 12, 2017

Related U.S. Application Data
(63) Continuation of application No. 14/232,593, filed on Jan. 13, 2014.

(30) Foreign Application Priority Data
Jul. 14, 2011 (KR) 10-2011-0070095

(51) Int. Cl. H01L 33/64; H01L 33/62; H01L 23/00; H01L 25/075

(52) U.S. Cl. CPC H01L 33/647; H01L 25/0753; H01L 33/62; H01L 24/48; H01L 2924/12041; H01L 2224/48139; H01L 2224/48505

(57) ABSTRACT

The present invention relates to a substrate for an optical device, which is configured to connect an optical element substrate and an electrode substrate in a fitting manner, and simultaneously, to form one or more bridge pads which are insulated from the optical element substrate by a horizontal insulating layer, on the optical element substrate. The substrate for an optical device according to a first aspect of the present invention comprises: an optical element substrate which is made of a metal plate and contains a plurality of optical elements therein; a pair of electrode substrates which are made of an insulating material to form a conductive layer on at least a portion of the upper surface thereof, are connected to both side surfaces of the optical element substrate, respectively, and are wire-bonded to the electrodes of the optical elements; and a fitting means which is formed on the side surfaces of the electrode substrate and the optical element substrate to fit the optical element substrate and the electrode substrate. The substrate for an optical device according to a second aspect of the present invention comprises: an optical element substrate which is made of a metal plate and contains a plurality of optical elements therein; a pair of electrode substrates which are made of a metal material to be connected to both side surfaces of the optical element substrate, respectively, and are wire-bonded to the electrodes of the optical elements; a fitting means which is formed on the side surfaces of the electrode substrate and the optical element substrate to fit the optical element substrate and the electrode substrate; and a fitting-type vertical insulating layer which is interposed between the optical element substrate and the electrode substrate so as to be connected to the fitting means.

### CROSS-REFERENCE TO RELATED APPLICATIONS

The present application is a continuation application of U.S. patent application Ser. No. 14/232,593, filed Jan. 13, 2014 naming Ki Myung Nam, Young Chul Jun, and Tae Hwan Song as inventors, and entitled “Substrate for Optical Device” [practitioner's file 3658H/132], which is a U.S. national phase entry of international patent application PCT/KR2012/005479 filed Jul. 11, 2012 and which is incorporated herein by reference, in its entirety, and which claims priority to Korean patent application 10-2011-0070095, filed Jul. 14, 2011.

### TECHNICAL FIELD

The present invention relates to a substrate for an optical device, and, more particularly to a substrate for an optical device, which is configured to connect an optical element substrate and an electrode substrate in a fitting manner, and simultaneously, to form one or more bridge pads, which are insulated from the optical element substrate by a horizontal insulating layer, on the optical element substrate.

### BACKGROUND ART

Generally, a light emitting diode (LED), which is semiconductor light-emitting device, has attracted considerable attention as an environment-friendly light source not causing environmental pollution in various fields. Recently, as the usage of LEDs was spread into various fields, such as interior and exterior illuminations, vehicle headlights, back-light units (BLUs) for displays, etc., LEDs having high efficiency and excellent heat dissipation characteristics have been required. In order to obtain a high-efficiency LED, the raw material or structure of an LED must be improved, and the structure of a LED package and the raw material used in the same are also required to be improved.

Since a high-efficiency LED generates high heat, when high heat is not effectively dissipated, the temperature of LED becomes high, so the characteristics of LED are deteriorated, thereby decreasing the lifespan of the LED. Therefore, efforts have been made to effectively dissipate the heat generated from such LEDs.

Hereinafter, various light-emitting elements, such as LEDs and the like, are referred to as “optical elements”, and various products, each including one or more optical elements, are referred to as “optical devices”.

FIGS. 1A to 1D are perspective views explaining a conventional method of manufacturing an optical device. First, as shown in FIG. 1A, in order to form a conventional substrate 10 for mounting an optical element, conductive plates 11, such as copper plates or the like, having predetermined thickness and insulating plates 12, such as glass epoxy plates or the like, are alternately attached to one another in a plane direction to form a block body 13 (refer to FIG. 1B). Here, the attachment of the conductive plates 11 and the insulating plates 12 may be conducted by an adhesive, thermal pressing or the like.

Subsequently, as shown in FIG. 1B, when the block body 13 shown in FIG. 1A is cut in a direction perpendicular to the plane of the conductive plate 11, that is, vertically cut, as shown in FIG. 1C, b, a substrate 10 including alternately disposed conductive strips 10a and insulating strip 10b is obtained.

Subsequently, as shown in FIG. 1D, the conductive strips (10a-\textcircled{1}, 10a-\textcircled{2}, 10a-\textcircled{3}) of the substrate 10 are respectively provided thereon with LED chips 2 disposed at regular intervals, each of the LED chips 2 provided on the conductive strips (10a-\textcircled{1}, 10a-\textcircled{2}, 10a-\textcircled{3}) is repeatedly connected to the subsequent conductive strip by a wire 3 to obtain an LED array, and then the LED array is molded with a transparent resin to prepare a plate-shaped LED array.

Meanwhile, the rows of the plate-shaped LED array are electrically connected in parallel to each other, and the lines thereof are electrically connected in series to each other. This plate-shaped LED array may be directly made into a product or may be made into a product by dividing the rows and lines into suitable row and line units or a single row and line unit. Moreover, when the plate-shaped LED array is directly used, it is mounted on a metal PCB or is provided at the lower portion thereof with a heat dissipation plate.

However, the above-mentioned conventional substrate for an optical device is problematic in that its conductive strips and insulating strips are attached by an adhesive or thermal pressing, and thus the connections between the conductive strips and the insulation strips are easily damaged by slight impact, bending or warping attributable to carelessness in treatment.

### DISCLOSURE

### Technical Problem

Accordingly, the present invention has been made to solve the above-mentioned problems, and an object of the present invention is to provide a substrate for an optical device, which is not damaged by impact, bending or warping attributable to carelessness in treatment because it is configured to connect an optical element substrate and an electrode substrate in a fitting manner, and simultaneously, not to form a horizontal insulating layer for insulating the optical element substrate into a plurality of regions.

Another object of the present invention is to provide a substrate for an optical device, which is not damaged by impact, bending or warping attributable to carelessness in treatment because it is configured to connect an optical element substrate and an electrode substrate in a fitting manner, and simultaneously, to form one or more bridge pads, which are insulated from the optical element substrate by a horizontal insulating layer, on the optical element substrate.

### Technical Solution

In order to accomplish the above objects, a first aspect of the present invention provides a substrate for an optical device, including: an optical element substrate which is made of a metal plate and is provided therein with a plurality of optical elements; a pair of electrode substrates which are made of an insulating material to form a conductive layer on at least a portion of the upper surface thereof, are connected to both side surfaces of the optical element substrate, respectively, and are wire-bonded to electrodes of the optical elements; and a fitting means which is formed on the side surfaces of the electrode substrate and the optical element substrate to fit the optical element substrate and the electrode substrate.

In the substrate for an optical device according to the first aspect of the present invention, the optical element substrate may be provided with a cavity including a rectangular groove mounted therein with a plurality of optical elements. Further, the optical element substrate may be provided with a plurality of cavities each including a groove mounted therein with an optical element.

A second aspect of the present invention provides a substrate for an optical device, including: an optical element substrate which is made of a metal plate and is provided therein with a plurality of optical elements; a pair of electrode substrates which are made of a metal material, are connected to both side surfaces of the optical element substrate, respectively, and are wire-bonded to electrodes of the optical elements; a fitting means which is formed on the side surfaces of the electrode substrate and the optical element substrate to fit the optical element substrate and the electrode substrate; and a fitting-type vertical insulating layer which is interposed between the optical element substrate and the electrode substrate so as to be connected to the fitting means.

In the substrate for an optical device according to the second aspect of the present invention, the fitting-type vertical insulating layer may be formed by anodizing the side surface of the optical element substrate and the electrode substrate including the fitting means.

Further, the optical element substrate may be provided with a cavity including a rectangular groove mounted therein with a plurality of optical elements. Further, the optical element substrate may be provided with a plurality of cavities each including a groove mounted therein with an optical element.

In the substrate for an optical device according to first or second aspect of the present invention, the optical element substrate may include a plated layer formed on an upper surface thereof. The substrate for an optical device first or second aspect of the present invention may further include: a horizontal insulating layer formed on at least one plated layer-removed region of the optical element substrate to be electrically connected with the plated layer; and a bridge pad disposed on the horizontal insulating layer to allow electrodes of the optical elements to be electrically connected by wires. In this case, the horizontal insulating layer may be formed in a groove formed in the plated layer-removed region of the optical element substrate.

### Advantageous Effects

The substrate for an optical device according to the present invention is advantageous in that it is not damaged by impact, bending or warping attributable to carelessness in treatment because it is configured to connect an optical element substrate and an electrode substrate in a fitting manner, and simultaneously, to form one or more bridge pads, which are insulated from the optical element substrate by a horizontal insulating layer, on the optical element substrate.

### DESCRIPTION OF DRAWINGS

FIGS. 1A to 1D are perspective views explaining a conventional method of manufacturing an optical device.

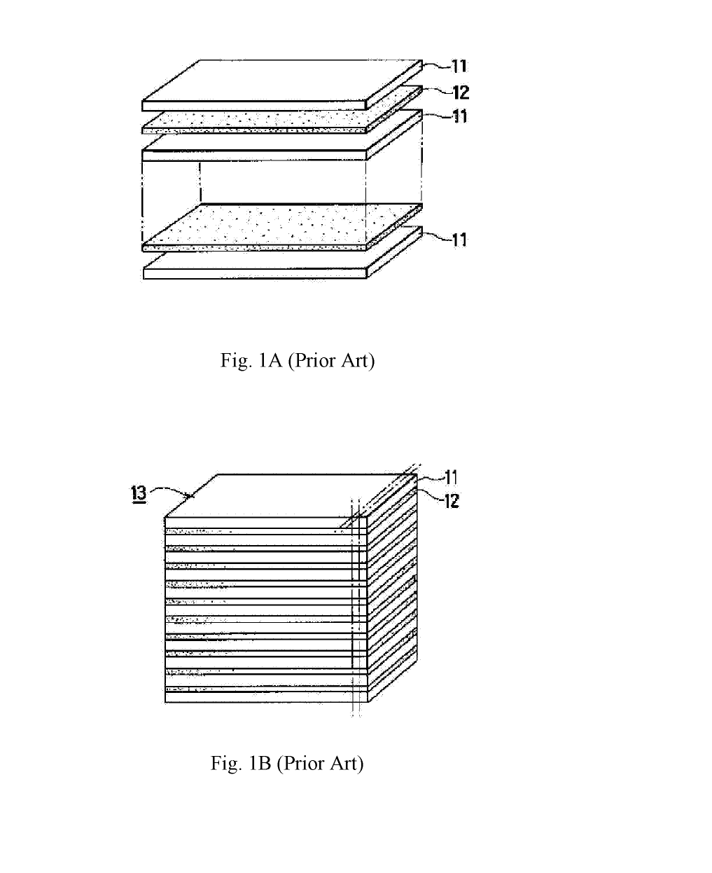

FIG. 2 is a sectional view of an optical device manufactured by a substrate for an optical device according to an embodiment of the present invention.

FIG. 3 is a sectional view of an optical device manufactured by a substrate for an optical device according to another embodiment of the present invention.

FIG. 4 is a sectional view of an optical device manufactured by the partially modified substrate for an optical device of FIG. 2, and FIG. 5 is a sectional view of an optical device manufactured by the partially modified substrate for an optical device of FIG. 3.

FIG. 6 is a sectional view of an optical device manufactured by chip-to-chip wire-bonding the electrodes of optical elements without interposing bridge pads.

FIG. 7A is a plan view of an optical device according to another embodiment of the present invention, and FIG. 7B is a sectional view of the optical device taken along the line A-A of FIG. 7A.

FIG. 8A is a plan view of an optical device according to another embodiment of the present invention, and FIG. 8B is a sectional view of the optical device taken along the line A-A of FIG. 8A.

### BEST MODE

Hereinafter, preferred embodiments of the present invention will be described in detail with reference to the attached drawings.

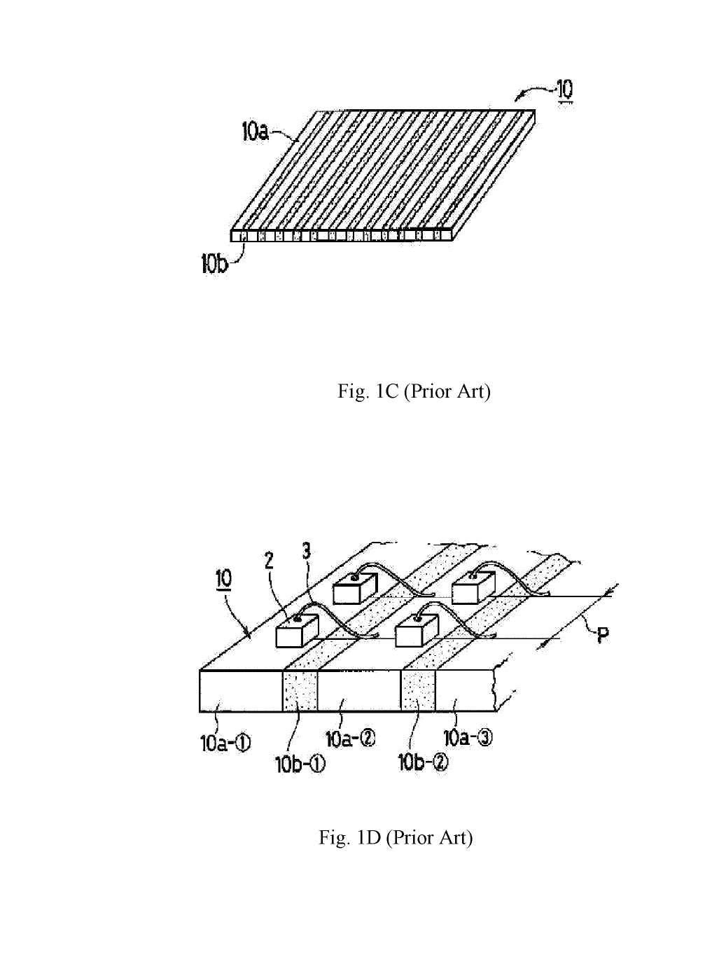

FIG. 2 is a sectional view of an optical device manufactured by a substrate for an optical device according to an embodiment of the present invention. As shown in FIG. 2, the optical device according to an embodiment of the present invention includes: an optical element substrate 110-1 which is located at the center of the optical device and is mounted with a plurality of optical elements 160; and a pair of electrode substrates 120-1 which are connected to both sides of the optical element substrate 110-1 in a fitting manner and function as the electrodes of the optical device, that is, the anode and the cathode.

As described above, the optical element substrate 110-1 may be formed of a metal plate which is made of a metal having high thermal conductivity, for example, aluminum (Al), magnesium (Mg), copper (Cu) or iron (Fe), or an alloy thereof in order to rapidly dissipate the heat generated from the optical elements 160. Further, each of the electrode substrates 120-1 may have a body which is made of a synthetic resin having good treatability and processibility, for example, a polymer, a plastic or a composite thereof because it does not need excellent heat dissipation characteristics compared to the optical element substrate 110-1. Therefore, FIG. 2 illustrates the electrode substrate 120-1 having a body which is made of a synthetic resin.

Meanwhile, in the present invention, in order to enhance the attachment between the optical element substrate 110-1 and the electrode substrate 120-1, both sides of the optical element substrate 110-1 are provided with protrusions 112, and one side of each of the electrode substrates 120-1 is provided with a groove 122 (refer to the structure in the dotted circle “A”), and thus the optical element substrate 110-1 is attached to each of the electrode substrates 120-1 by fitting the protrusion 112 in the groove 122. In this case, the protrusion 112 and the groove 122 may be formed crosswise over the entire or partial sides of the optical element substrate 110-1 and the electrode substrate 120-1, respectively. Meanwhile, as shown in the dotted circle “B” of FIG. 2, each of the electrode substrate 120-1 may be provided at one side thereof with a protrusion 123, and the optical element substrate 110-1 may be provided at both sides thereof with grooves 113. Further, the optical element substrate 110-1 may be vertically provided at each side thereof with two or more protrusions, and each of the electrode substrates 120-1 may be provided at one side thereof with two or more grooves. Further, the optical element substrate 110-1 may be vertically provided at each side thereof with two or more grooves, and each of the electrode substrates 120-1 may be provided at one side thereof with two or more protrusions. In contrast with above, the optical element substrate 110-1 may be provided at one side thereof with a protrusion, and may be provided at the other side thereof with a groove. The protrusion 112 and the groove 122 may be formed by a machining process.

Meanwhile, as shown in FIG. 2, when the body of the electrode substrate 120-1 is made of a synthetic resin, a conductive layer 134 must be formed on the entire or partial upper surface of the body thereof such that this body functions as the electrode substrate 120-1. Meanwhile, the optical element 160 may be directly attached to the upper surface of the metal plate constituting the optical element substrate 110-1 to be mounted on the optical element substrate 110-1, but, in this case, the reflectance of light incident on the upper surface of the optical element substrate 110-1 may be lowered because of interference, so it is preferred that a plated layer 132 having high optical reflectance be formed on the upper surface of the optical element substrate 110-1. The plate layer 132 may be made of silver (Ag) having high optical reflectance.

In the present invention, in order to prevent the optical element substrate 110-1 from being provided with a vertical insulating layer, the optical element substrate 110-1 is provided thereon with at least one horizontal insulating layer 140 electrically insulated from this optical element substrate 110-1, and the horizontal insulating layer 140 is provided thereon with a bridge pad 150 for electrically connecting two adjacent optical elements 160.

Here, the horizontal insulating layer 140 may be formed by attaching a synthetic resin sheet onto the optical element substrate 110-1 using an adhesive or thermal pressing, by curing a liquid epoxy or silicon adhesive or by directly thermal-spray ceramic onto the optical element substrate 110-1. In this case, in order to increase the adhesion between the horizontal insulating layer 140 and the optical element substrate 110-1, the horizontal insulating layer 140 may be formed after making the surface of the optical element substrate 110-1 rough as pretreatment. Meanwhile, in order to prevent the horizontal insulating layer 140 from deteriorating the optical reflection efficiency of the optical element substrate 110-1, the size of the horizontal insulating layer 140 may be reduced, if possible.

The bridge pad 150 may be formed of a metal or alloy sheet having excellent electroconductivity, light reflectance and adhesivity with wire, selected from among gold (Au), silver (Ag), copper (Cu), aluminum (Al), nickel (Ni) and alloys thereof. Preferably, the bridge pad 150 may be formed by attaching a silver (Ag) sheet onto the horizontal insulating layer 140 using an adhesive. The bridge pad 150 may have various shapes, such as a circle, a quadrangle and the like.

Further, the bridge pad 150 may be formed by treating a silicon wafer with the metal material using sputtering, electroplating or electroless plating or treating a plastic or FR4 plate with the metal material using electroplating or electroless plating to form a plated layer, suitably cutting the plated layer and then attaching the cut plated layer onto the horizontal insulating layer 140 using an adhesive. Furthermore, the bridge pad 150 may be formed by directly printing silver (Ag) paste onto the horizontal insulating layer 140 using screen printing. Meanwhile, in order to increase the reliability of wire bonding, an electroless nickel (Ni) plated layer may be additionally formed on the surface of the bridge pad 150. It is preferred that the size of the bridge pad 150 be smaller than that of the horizontal insulating layer 140 such that the electrical insulation between adjacent plated layers 132 of the optical element substrate 110-1 is sufficiently conducted.

Meanwhile, after the optical element substrate 110-1 is attached to the electrode substrates 120, a single plated layer 130 is formed thereon. This single plated layer 130 is separated into a conductive layer 134 and a plated layer 132 by a mechanical process (for example, a cutting process) or a chemical process (for example, an etching process) together with a region in which a horizontal insulating layer 140 is to be occupied, and then subsequent processes may be performed.

Through the above-mentioned processes, a substrate for an optical device is completed. Thereafter, optical elements 160 are mounted on the plated layers 132 provided therebetween with the bridge pad 150 by an adhesive or the like, and then the optical elements 160 are electrically connected to each other by wire bonding through the intermediation of the bridge pad 150. In this case, the respective electrodes of the leftmost and rightmost optical elements 160 are electrically connected to the respective electrode substrates 120-1 through wires 165. In FIG. 2, the reference numeral “190” indicates a transparent or fluorescent material-containing sealant for protecting optical elements 160 and wires 165, and the reference numeral “180” indicates a dam for confining the liquid sealant 190.

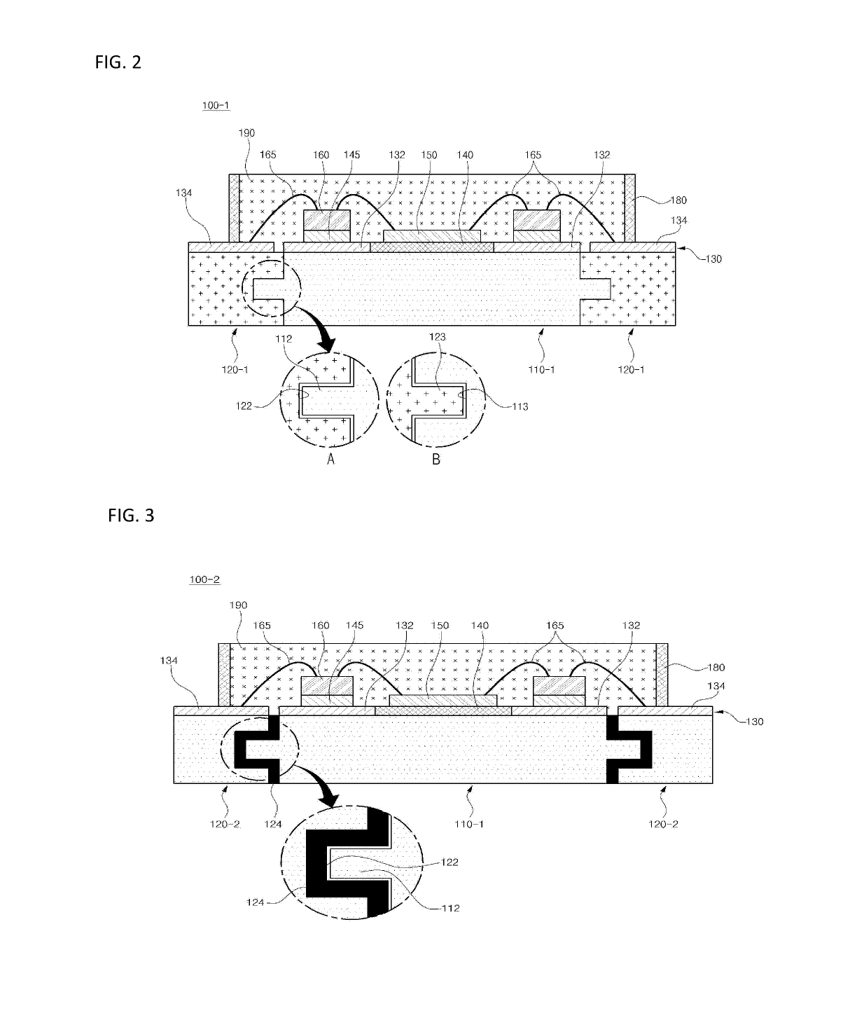

FIG. 3 is a sectional view of an optical device manufactured by a substrate for an optical device according to another embodiment of the present invention. In FIG. 3, the same components as those in FIG. 2 are conferred with same reference numerals, and detailed descriptions thereof will be omitted. According to the optical device 100-2 shown in FIG. 3, an electrode substrate 120-2 may be formed of a metal plate (for example, the same metal plate as that of the optical element substrate 110-1) rather than a synthetic resin. In this case, for the purpose of insulating the electrode substrate 120-2 and the optical element substrate 110-1, a fitting-type vertical insulating layer 124 having a laterally-laid cap shape must be interposed between these substrates such that the protrusion 112 of the optical element substrate 110-1 is fitted with the groove 122 of the electrode substrate 120-2. Such a fitting-type vertical insulating layer 124 is made of a synthetic resin, and is attached to the optical element substrate 110-1 and the electrode substrate 120-2 by an adhesive. Meanwhile, the fitting-type vertical insulating layer may be integrated with the optical element substrate 110-1 or the electrode substrate 120-2 by anodizing the lateral side of the optical element substrate 110-1 having a protrusion 112 or the electrode substrate 120-2 having a groove 122 or by anodizing the lateral side of the optical element substrate 110-1 having a groove 122 or the electrode substrate 120-2 having a protrusion 112. Here, the fitting structure is the same as that shown in FIG. 2.

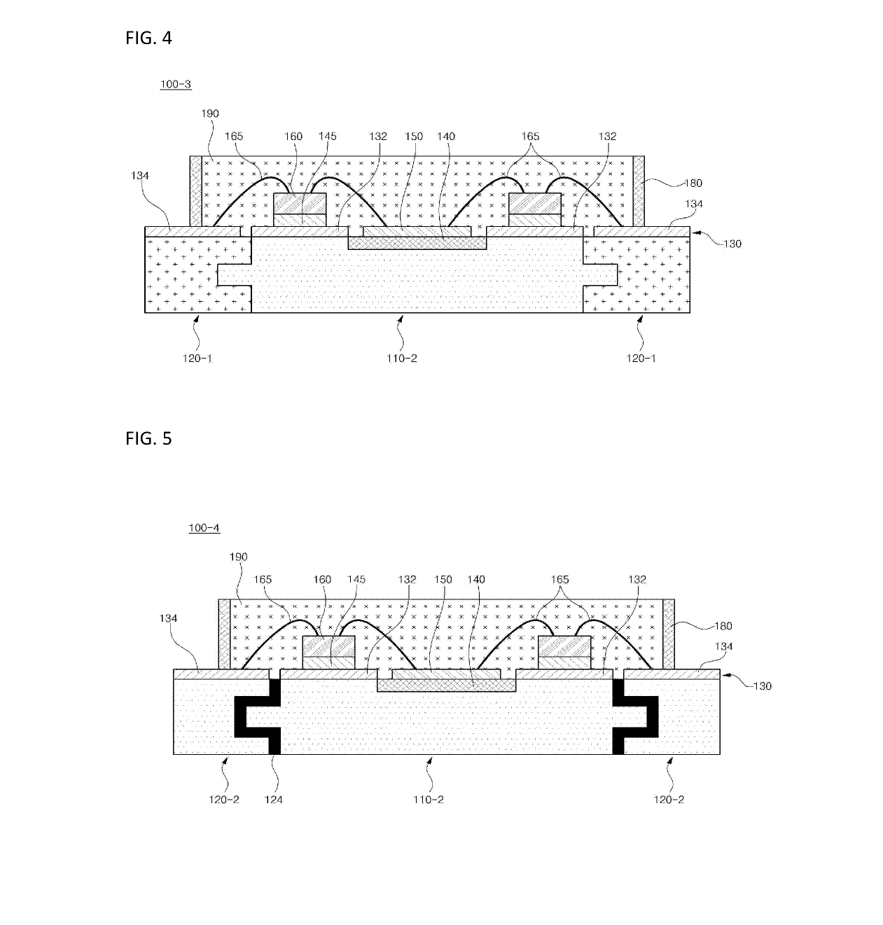

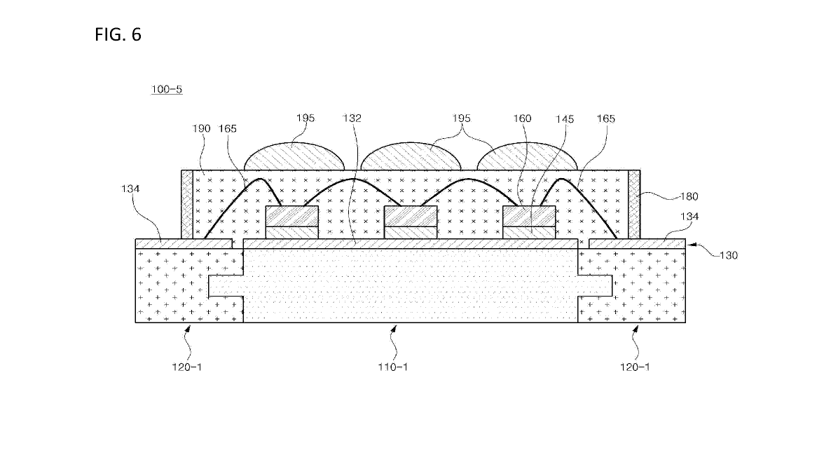

FIG. 4 is a sectional view of an optical device manufactured by the partially modified substrate for an optical device of FIG. 2, and FIG. 5 is a sectional view of an optical device manufactured by the partially modified substrate for an optical device of FIG. 3. In FIGS. 4 and 5, the same components as those in FIGS. 2 and 3 are conferred with same reference numerals, and detailed descriptions thereof will be omitted. In the optical devices (100-3 and 100-4) shown in FIGS. 4 and 5, in order to prevent the deterioration of the optical reflectance occurring when the upper surface of the bridge pad 150 is higher than the upper surface of the plated layer 132 due to the thickness of the horizontal insulating layer 140, a mounting groove is formed in the upper portion of the optical element substrate 110-2 to a depth corresponding to the thickness of the horizontal insulating layer 140, and then this horizontal insulating layer 140 is mounted in the mounting groove. Consequently, even when the bridge pad 150 is disposed on the horizontal insulating layer 140, the upper surface of the bridge 150 is flush with or lower than the upper surface of the plated layer 132, thus preventing the deterioration of optical reflectance. In FIGS. 2 to 5, for convenience, optical devices each having two optical elements 160 are shown, optical devices each having two or more optical elements 160 may also be manufactured. Moreover, the optical devices shown in FIGS. 2 to 5 can be preferably applied when the distance between optical elements is large enough that chip to chip wire bonding cannot be performed as in the following optical device shown in FIG. 6.

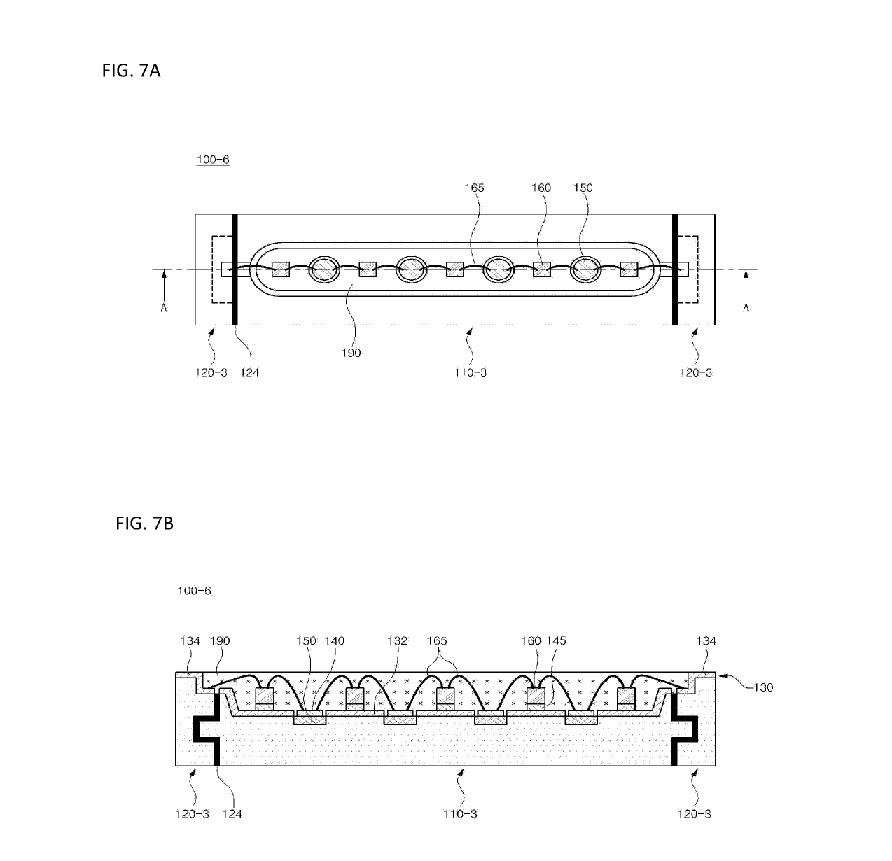

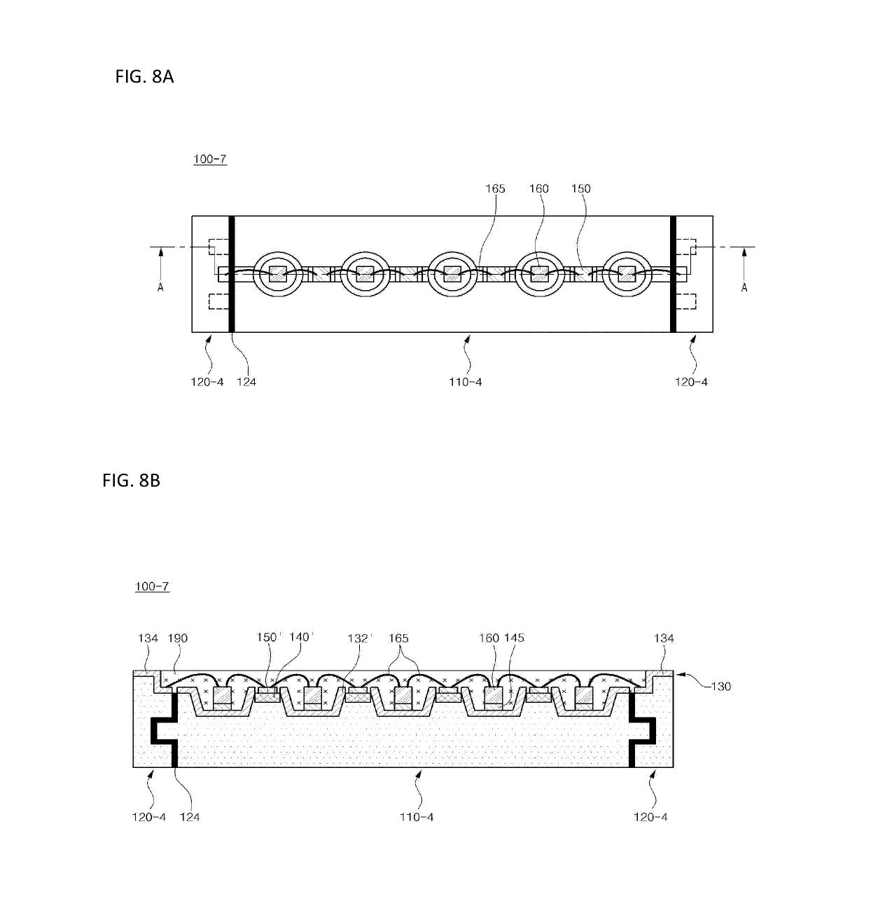

FIG. 6 is a sectional view of an optical device manufactured by chip-to-chip wire-bonding the electrodes of optical elements without interposing bridge pads. In FIG. 6, the same components as those in FIGS. 2 to 5 are conferred with same reference numerals, and detailed descriptions thereof will be omitted. In the optical device 100-5 shown in FIG. 6, this optical device 100-5 does not include bridge pads, so it does not need a horizontal insulating layer, and thus a plated layer may be formed over the entire region of an optical element substrate. The optical device according to this embodiment may be applied to an optical device required to maintain the intervals among optical elements narrow. In FIG. 6, the reference numeral “195” indicates a lens (convex lens) for focusing light emitted from an optical element (in the case of dispersing light: a concave lens). Such a lens may be directly applied to the following optical devices shown in FIGS. 7 and 8 as well as the above-mentioned optical devices shown in FIGS. 2 to 5.

FIG. 7A is a plan view of an optical device according to another embodiment of the present invention, and FIG. 7B is a sectional view of the optical device taken along the line A-A of FIG. 7A. In FIGS. 7A and 7B, the same components as those in FIGS. 2 to 5 are conferred with same reference numerals, and detailed descriptions thereof will be omitted. As shown in FIGS. 7A and 7B, in the optical device 100-6 according to an embodiment of the present invention, a single cavity having a rectangular groove is formed in the upper portion of an optical element substrate 110-3, and this cavity is mounted therein with a plurality of optical elements 160. In this case, when the cavity is formed in an incline shape such that the width of the upper portion of the wall of the cavity is larger than that of the lower portion of the wall thereof, optical reflectance can be improved.

Meanwhile, in this configuration, it preferred that a sealant 190 be charged in the cavity to a level of the upper surface thereof. In this case, steps may be provided over parts of the optical element substrate 110-3 and the electrode substrate 120-3 including the fitting-type vertical insulating layer 124 therebetween such that the wire 165 connected to the electrode substrate 120-3 is embedded in the sealant 190. The cavity may be formed by a pressing, cutting or etching process in a state in which the optical element substrate 110-3 and the electrode substrate 120-3 are attached by fitting. Unlike this, the cavity and the steps are formed in a state in which the optical element substrate 110-3 and the electrode substrate 120-3 are detached from each other, and then the optical element substrate 110-3 and the electrode substrate 120-3 are attached by fitting.

FIG. 8A is a plan view of an optical device according to another embodiment of the present invention, and FIG. 8B is a sectional view of the optical device taken along the line A-A of FIG. 8A. In FIGS. 8A and 8B, the same components as those in FIGS. 2 to 5 are conferred with same reference numerals, and detailed descriptions thereof will be omitted. As shown in FIGS. 8A and 8B, in the optical device 100-7 according to an embodiment of the present invention, in order to further increase optical reflectance, optical elements are mounted in respective cavities, each of which is formed of a groove having an incline whose upper portion is wide and whose lower portion is narrow. Therefore, the optical element substrate is provided with a plurality of cavities. Meanwhile, in this embodiment, channel grooves, each having a smaller width than a cavity, are formed between the cavities, and a horizontal insulating layer is formed in each of the channel grooves, and a bridge pad is disposed on the horizontal insulating layer, so the upper plane of the cavity is flush with the upper surface of the bridge bad, thereby increasing optical reflectance.

In FIGS. 2 to 8, unless otherwise explained, the same materials and functional components are indicated using the same hatching.

The substrate for an optical device according to the present invention may be variously modified within the scope of the technical idea of the present invention without being limited to the above-mentioned embodiments. The substrate for an optical device according to the present invention may also be applied to a light source for backlight unit in which a plurality of optical elements are serially aligned in a series connection.

### DESCRIPTION OF THE REFERENCE NUMERALS IN THE DRAWINGS

100-1˜100-7: optical device

110-1˜110-4: optical element substrate

112: protrusion

120-1˜120-4: electrode substrate

122: groove

124: fitting-type vertical insulating layer

130: plated layer

132: plated layer

134: conductive layer

140: horizontal insulating layer

150: bridge pad

160: optical element

165: wire

180: sealant dam

190: sealant

195: lens

What is claimed is:

1. An optical device, comprising:
a first substrate provided with a plurality of optical elements;
a pair of second substrates formed on both side surfaces of the first substrate, respectively;
an insulating layer disposed between the first substrate and the second substrates to electrically insulate the first substrate from the second substrates; and
a bridge pad formed on the first substrate,
wherein the first substrate and the second substrates are made of a same metal,
the insulating layer is formed by anodizing a side surface of the first substrate or the second substrates,
the plurality of optical elements are electronically connected to one another via the bridge pad by wire bonding, an electrode of a leftmost optical element of the first substrate is electronically connected to one of the second substrates by wire bonding, and an electrode of a rightmost optical element of the first substrate is electronically connected to the other of the second substrates by wire bonding.

2. The optical device according to claim 1, wherein the bridge pad is made of gold (Au), silver (Ag), copper (Cu), aluminum (Al) or nickel (Ni), or an alloy thereof.
